(19) United States
(12) Patent Application Publication
(10) Pub. No.: US 2020/0144327 A1
(43) Pub. Date: May 7, 2020

(54) LIGHT EMITTING DIODE MODULE AND DISPLAY DEVICE

(71) Applicant: SAMSUNG ELECTRONICS CO., LTD., Suwon-si (KR)

(72) Inventors: Jin Sub LEE, Suwon-si (KR); Hye Seok NOH, Suwon-si (KR); Han Kyu SEONG, Seoul (KR); Young Jin CHOI, Seoul (KR)

(21) Appl. No.: 16/455,031

(22) Filed: Jun. 27, 2019

(30) Foreign Application Priority Data
Nov. 5, 2018 (KR) 10-2018-0134681

(51) Int. Cl. H01L 27/15; H01L 33/50; H01L 33/38; H01L 33/46; H01L 25/10; H01L 33/62; H01L 33/52; H01L 33/60

(52) U.S. Cl. CPC H01L 27/156; H01L 33/505; H01L 33/38; H01L 33/46; H01L 33/502; H01L 33/62; H01L 33/52; H01L 33/60; H01L 2933/0091; H01L 25/105

(57) ABSTRACT

A light emitting diode module includes a cell array including first to fourth light emitting diode cells, each cell having a first conductive semiconductor layer, an active layer, and a second conductive semiconductor layer, the cell array having a first surface and a second surface opposite to the first surface; first to fourth light adjusting portions on the second surface of the cell array to respectively correspond to the first to fourth light emitting diode cells, to provide red light, first green light, second green light, and blue light, respectively; light blocking walls between the first to fourth light adjusting portions to isolate the first to fourth light adjusting portions from one another; and an electrode portion on the first surface of the cell array, and electrically connected to the first to fourth light emitting diode cells to selectively drive the first to fourth light emitting diode cells.

### CROSS-REFERENCE TO RELATED APPLICATION

Korean Patent Application No. 10-2018-0134681 filed on November 5, 2018 in the Korean Intellectual Property Office, and entitled: “Light Emitting Diode Module and Display Device,” is incorporated by reference herein in its entirety.

### BACKGROUND

### Field

The present disclosure relates to a light emitting diode module and a display device.

### 2. Description of the Related Art

Semiconductor light emitting diodes (LEDs) have been used as light sources in various electronic products as well as in lighting devices. For example, semiconductor LEDs have commonly been used as light sources for a variety of display devices such as TVs, mobile phones, PCs, laptops, personal digital assistants (PDAs), and the like.

A display solution that can provide a broad color gamut covering various color standards (e.g., s-RGB, DCI, and BT.2020) is desired. Such a display solution may be implemented by developing a light source having improved color reproducibility.

### SUMMARY

According to an example embodiment, a light emitting diode module includes a cell array including first to fourth light emitting diode cells each having a first conductive semiconductor layer, an active layer, and a second conductive semiconductor layer, and having a first surface and a second surface opposite to the first surface; first to fourth light adjusting portions on the second surface of the cell array respectively on the first to fourth light emitting diode cells to provide red light, first green light, second green light, and blue light, respectively; light blocking walls between the first to fourth light adjusting portions to isolate the first to fourth light adjusting portions from one another; and an electrode portion on the first surface of the cell array, and electrically connected to the first to fourth light emitting diode cells to selectively drive the first to fourth light emitting diode cells.

According to an example embodiment, a light emitting diode module includes a cell array including first to fourth light emitting diode cells each having first and second conductive semiconductor layers, and an active layer between the first and second conductive semiconductor layers and emitting blue light having a peak wavelength of 460 nm to 470 nm, the cell array having a first surface and a second surface opposite to the first surface; reflective insulating portions respectively surrounding the first to fourth light emitting diode cells to isolate the first to fourth light emitting diode cells from one another; light blocking walls in regions corresponding to the reflective insulating portions, and providing first to fourth windows respectively opening the first to fourth light emitting diode cells; first to third light adjusting portions respectively on the first to third windows, and converting the blue light into red light, first green light, and second green light; and an electrode portion on the first surface of the cell array, and electrically connected to the first to fourth light emitting diode cells to selectively drive the first to fourth light emitting diode cells. The first green light has a peak wavelength of 510 nm to 525 nm and a full width at half maximum of 50 nm or less, the second green light has a peak wavelength of 530 nm to 540 nm and a full width at half maximum of 55 nm or less, and the red light has a peak wavelength of 620 nm to 640 nm and a full width at half maximum of 30 nm or less.

### BRIEF DESCRIPTION OF THE DRAWINGS

Features will become apparent to those of skill in the art by describing in detail exemplary embodiments with reference to the attached drawings in which:

FIGS. 1 and 2 illustrate a top diagram and a bottom diagram, respectively, of a light emitting diode (LED) module according to respective example embodiments;

FIGS. 3A and 3B illustrate side cross-sectional diagrams respectively taken along lines I1-I1′ and I2-I2′ of an LED module of FIGS. 1 and 2;

FIG. 4 illustrates a side cross-sectional diagram taken along a line II-II' of an LED module of FIGS. 1 and 2;

FIG. 5 illustrates a graph of a light emitting spectrum of first green light of an LED module according to an example embodiment;

FIG. 6 illustrates light emitting spectrums of an LED module according to an example embodiment;

FIG. 7 illustrates graphs of color reproducibility of an LED module represented in the CIE 1931 coordinate system according to an example embodiment;

FIGS. 8 and 9 illustrate a top diagram and a bottom diagram, respectively, illustrating an LED module according to example embodiments;

FIGS. 10A and 10B illustrate side cross-sectional diagrams taken along lines I1-I1′ and I2-I2′ of an LED module of FIGS. 8 and 9, respectively;

FIG. 11 illustrates a side cross-sectional diagram taken along a line II-II′ of an LED module of FIGS. 8 and 9;

FIG. 12 illustrates a perspective diagram of a display panel in which an LED module illustrated in FIG. 1 is employed;

FIG. 13 illustrates a diagram of an example of a circuit of a pixel region of a display panel illustrated in FIG. 12; and

FIG. 14 illustrates a block diagram of a display device according to example embodiments.

### DETAILED DESCRIPTION

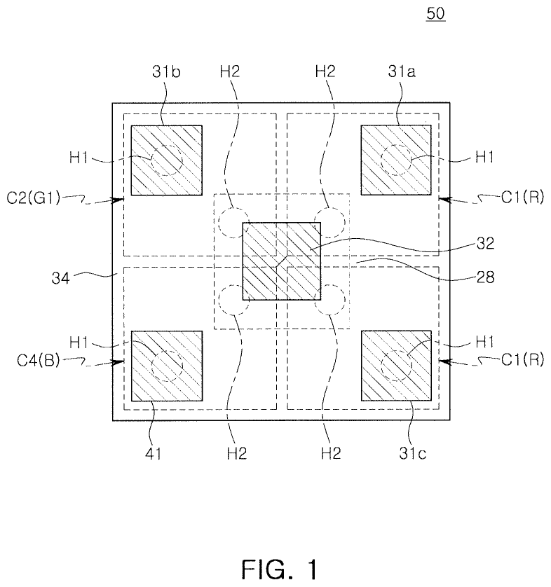

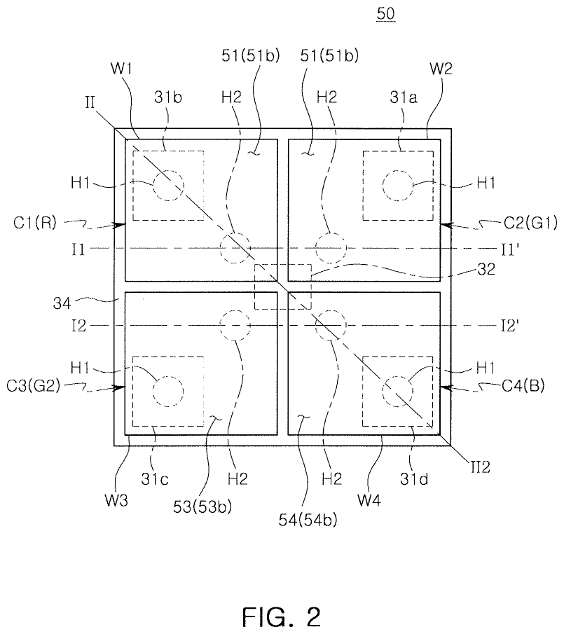

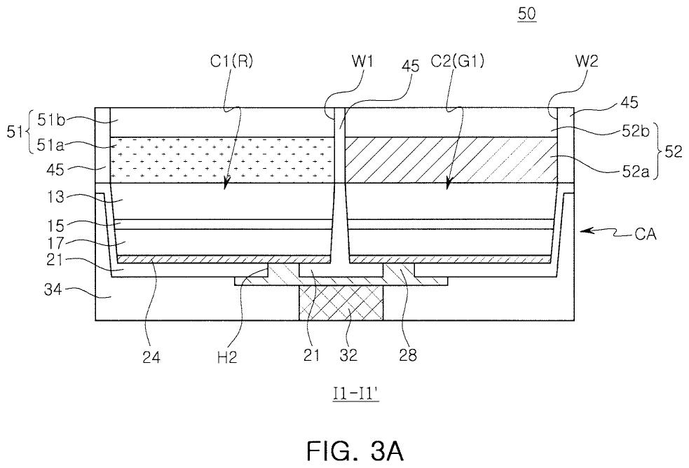

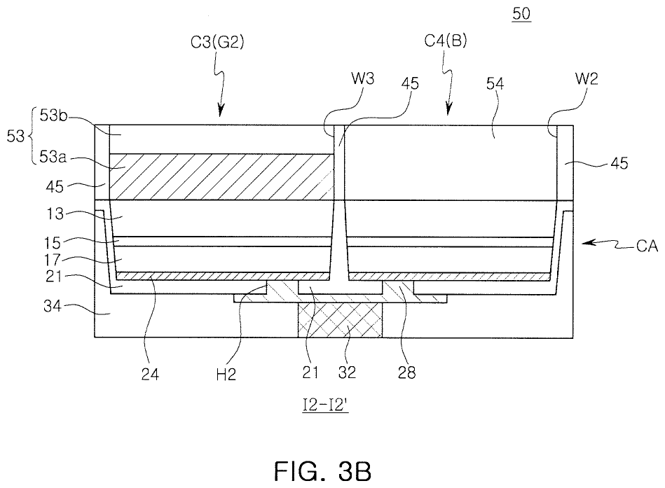

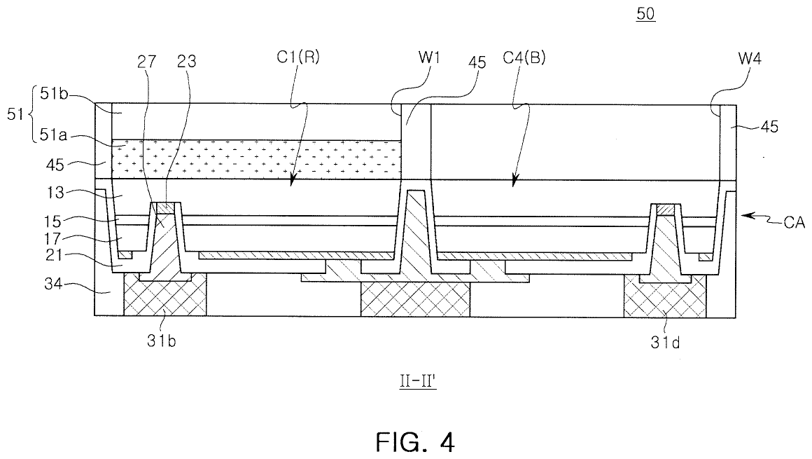

FIGS. 1 and 2 are a top diagram and a bottom diagram, respectively, illustrating a light emitting diode (LED) module according to respective example embodiments. FIGS. 3A and 3B are side cross-sectional diagrams respectively taken along lines I1-I1′ and I2-I2′ of an LED module of FIGS. 1 and 2. FIG. 4 is a side cross-sectional diagram taken along a line II-II′ of an LED module of FIGS. 1 and 2.

Referring to FIGS. 3A, 3B, and 4 along with FIGS. 1 and 2, a light emitting diode module 50 may include a cell array CA having first to fourth light emitting diode cells C1, C2, C3, and C4, first to fourth light adjusting portions 51, 52, 53, and 54 on a first surface of the cell array CA to correspond to the first to fourth light emitting diode cells C1, C2, C3, and C4, and light blocking walls 45 isolating the first to fourth light adjusting portions 51, 52, 53, and 54 from one another.

As illustrated in FIGS. 3A and 3B, the first to fourth light emitting diode cells C1, C2, C3, and C4 each may include epitaxial layers including a first conductive semiconductor layer 13, an active layer 15, and a second conductive semiconductor layer 17 stacked along a stacking direction. The epitaxial layers 13, 15, and 17 may be grown in the same process in a single wafer. The active layers 15 of the first to fourth light emitting diode cells C1, C2, C3, and C4 may emit light of the same wavelength. For example, the active layer 15 may emit blue light (e.g., 460 nm to 470 nm) or ultraviolet/near ultraviolet light.

The cell array CA may include insulating portions 21 respectively surrounding the first to fourth light emitting diode cells C1, C2, C3, and C4. The insulating portions 21 may electrically isolate the first to fourth light emitting diode cells C1, C2, C3, and C4 from one another. As illustrated in FIGS. 3A and 3B, the insulating portions 21 may be extend beneath the epitaxial layers and along sidewalls thereof. The insulating portions 21 may have surfaces substantially coplanar with light emitting surfaces (surfaces in contact with the first to fourth light adjusting portions 51, 52, 53, and 54) of the first to fourth light emitting diode cells C1, C2, C3, and C4. The coplanar surfaces may be provided the first surface of the cell array CA and may be obtained by removing a wafer used as a growth substrate after processes of isolating the cells and forming the insulating portions.

The first to fourth light adjusting portions 51, 52, 53, and 54 may convert light emitted from the first to fourth light emitting diode cells C1, C2, C3, and C4 into different colors of light. The light blocking walls 45 may extend from the surface of the insulating portions 21 along the first to fourth light adjusting portions 51, 52, 53, and 54, and may have surfaces coplanar with the first to fourth light adjusting portions 51, 52, 53, and 54. Thus, according to the example embodiment, the light emitting diode module 50 emit four beams of light having different colors to improve color reproducibility and may be used as a light source for a display.

The first to fourth light adjusting portions 51, 52, 53, and 54 in the example embodiment may respectively provide red light R, first green light G1, second green light G2, and blue light B. A general light source for a display has three primary colors, red, green, and blue, whereas, in the example embodiment, green light emitted from the light emitting diode module 50 may be reproduced as the first green light G1 and the second green light G2 such that a color gamut may be broadened.

In the example embodiments, the first green light G1 may have a peak wavelength of 510 nm to 525 nm, and the second green light G2 may have a peak wavelength of 530 nm to 540 nm. The first green light G1 and the second green light G2 each may also have a full width at half maximum of 55 nm or less (e.g., 50 nm or less). For example, the first green light G1 may have a full width at half maximum of 50 nm or less, and the second green light G2 may have a full width at half maximum of 55 nm or less. The blue light B may have a peak wavelength of 460 nm to 470 nm, and the red light R may have a peak wavelength of 620 nm to 640 nm. The blue light B and the red light R each may have a full width at half maximum of 30 nm or less. Herein, peak wavelength means a wavelength at which the spectrum reaches its highest intensity.

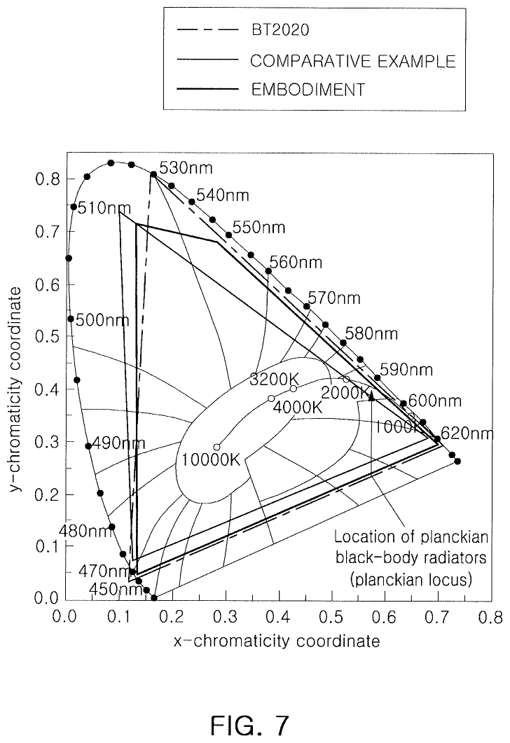

By configuring the four colors emitted from the light emitting diode module 50 to have the above described peak wavelengths and full widths at half maximum, improved color reproducibility may be implemented. In the example embodiments, a color gamut of the light emitting diode module 50 may cover 90% or higher of a BT.2020 region in the CIE 1931 coordinate system, which will be described in greater detail later (see FIG. 7).

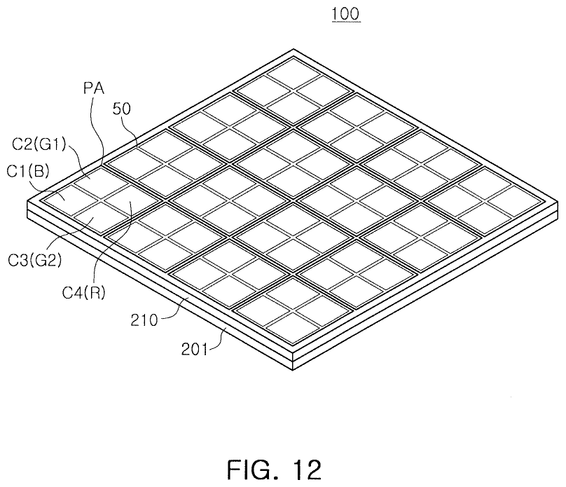

Referring to FIGS. 3A, 3B, and 4, the fourth light adjusting portion 54 may include a transparent resin layer which does not include a wavelength converting material, whereas the first to third light adjusting portions 51, 52, and 53 may respectively include first to third wavelength converting portions 51a, 52a, and 53a. The first to third wavelength converting portions 51a, 52a, and 53a each may include a wavelength converting material for converting the blue light B emitted from the first to third light emitting diode cells C1, C2, and C3 into the red light R, the first green light G1, and the second green light G2, respectively. The wavelength converting material may include a phosphor and/or a quantum dot for converting light into light under desired conditions (e.g., a peak wavelength and a full width at half maximum). The wavelength converting material employed in the example embodiment will be described in greater detail later (see FIG. 12).

In the example embodiments, the first to third wavelength converting portions 51a, 52a, and 53a may be provided as films. For example, the first to third wavelength converting portions 51a, 52a, and 53a may be provided as ceramic phosphor films, or resin layers containing a phosphor or a quantum dot, but an example embodiment thereof is not limited thereto. The first to third wavelength converting portions 51a, 52a, and 53a may be formed through different processes. For example, the first to third wavelength converting portions 51a, 52a, and 53a may be formed by dispensing a light-transmittable liquid resin containing a certain amount of wavelength converting material to first to third windows W1, W2, and W3.

In the example embodiment, the first to fourth light emitting diode cells C1, C2, C3, and C4 may have the active layers 15 emitting blue light, and as illustrated in FIGS. 3A and 3B, the first light adjusting portion 51 may include the first wavelength converting portion 51a emitting red light. Also, the second and third light adjusting portions 52 and 53 may include the second and third wavelength converting portions 52a and 53a respectively emitting first green light and second green light having different wavelengths.

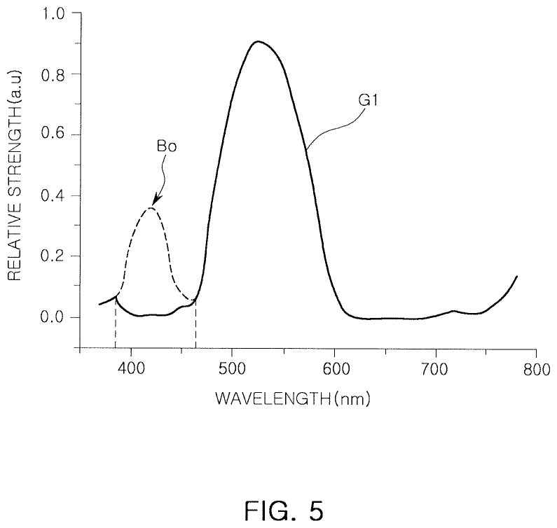

In the example embodiments, the first to third light adjusting portions 51, 52, and 53 may respectively further include first to third light filtering layers 51b, 52b, and 53b on the first to third wavelength converting portions 51a, 52a, and 53a. The first to third light filtering layers 51b, 52b, and 53b may allow only red light, first green light, and second green light to be emitted from the first to third windows W1, W2, and W3, respectively. The first to third light filtering layers 51b, 52b, and 53b may selectively block blue light which is not converted by the first to third wavelength converting portions 51a, 52a, and 53a. In the description below, a process of filtering the first green light G1 will be described with reference to FIG. 5 as an example. FIG. 5 illustrates a light emitting spectrum of the first green light G1 of the light emitting diode module.

Referring to FIG. 5, a peak B0 of blue light, which has not been converted by second wavelength converting portion 52a, and a peak of the first green light G1 are output from the second wavelength converting portion 52a. The non-converted blue light B0 may be blocked using the second light filtering layer 52b, thereby improving purity of the first green light G1. For example, the first to third light filtering layers 51b, 52b, and 53b may have filtering ranges with a peak wavelength of 480 nm to 500 nm, and a full width at half maximum of 80 nm to 100 nm.

The insulating portions 21 may be a material having electrical insulation properties. For example, the insulating portions 21 may be a silicon oxide, a silicon oxynitride, a silicon nitride, and the like. The insulating portions 21 in the example embodiment may further include a material having a low light absorption rate or low reflectivity, or a reflective structure. The insulating portions 21 may block interactive optical interference such that the first to fourth light emitting diode cells C1, C2, C3, and C4 may operate independently.

In the example embodiment, the insulating portions 21 may include a distributed Bragg reflector structure in which a plurality of insulating films having different refractive indices are alternately layered. The DBR structure may be formed by repeatedly layering the plurality of insulating films having different refractive indices twice up to hundreds of times. The plurality of insulating films may be selected from an oxide or a nitride such as SiO₂, SiN, SiOxNy, TiO₂, Si₃N₄, Al₂O₃, ZrO₂, TiN, AIN, TiAlN, TiSiN, and the like.

The light blocking walls 45 may be connected to the insulating portions 21. Accordingly, the light blocking walls 45 and the insulating portions 21 may be provided as a light blocking structure extending from portions among the first to fourth light emitting diode cells C1, C2, C3, and C4 to portions among the first to fourth light adjusting portions 51, 52, 53, and 54, and optical interference may be prevented effectively in an overall light path by the light blocking structure. Thus, the light emitting diode module 50 may be provided as a single pixel of a display, and the first to fourth light emitting diode cells C1, C2, C3, and C4 may be selectively driven as sub-pixels to provide desired colors of light.

The light emitting diode module 50 in the example embodiment may include various forms of electrode portions to selectively drive the first to fourth light emitting diode cells C1, C2, C3, and C4.

Referring to FIGS. 1 to 4, the light emitting diode module 50 may include an electrode portion electrically connected to the first to fourth light emitting diode cells C1, C2, C3, and C4 on a second surface of the cell array CA. The electrode portion may selectively drive the first to fourth light emitting diode cells C1, C2, C3, and C4. The electrode portion in the example embodiment may include four first electrode pads 31a, 31b, 31c, and 31d respectively connected to the four cells C1, C2, C3, and C4, and a second electrode pad 32 commonly connected to the four first electrode pads 31a, 31b, 31c, and 31d.

For example, referring to FIGS. 3A, 3B and 4, the four first electrode pads 31a, 31b, 31c, and 31d may be independently connected to the first conductive semiconductor layers 13 of the four first electrode pads 31a, 31b, 31c, and 31d by four first connection electrodes 27, respectively. For example, the second connection electrode 27 may extend along portions of the epitaxial layers to contact the first conductive semiconductor layer 13 and may have sidewalls surrounded by the insulating portion 21. The second electrode pad 32 may be commonly connected to the second conductive semiconductor layers 17 of the first to fourth light emitting diode cells C1, C2, C3, and C4 by a single second connection electrode 28. The first and second connection electrodes 27 and 28 may respectively be connected to the first and second conductive semiconductor layers 13 and 17 through first and second through-holes H1 and H2 formed through the insulating portions 21.

The electrode portion in the example embodiment may further include first and second contact electrodes 23 and 24. The first contact electrode 23 may contact the first conductive semiconductor layer 13. The second contact electrode 24 may be on the second conductive semiconductor layer 17 and covered by the insulating layer 21.

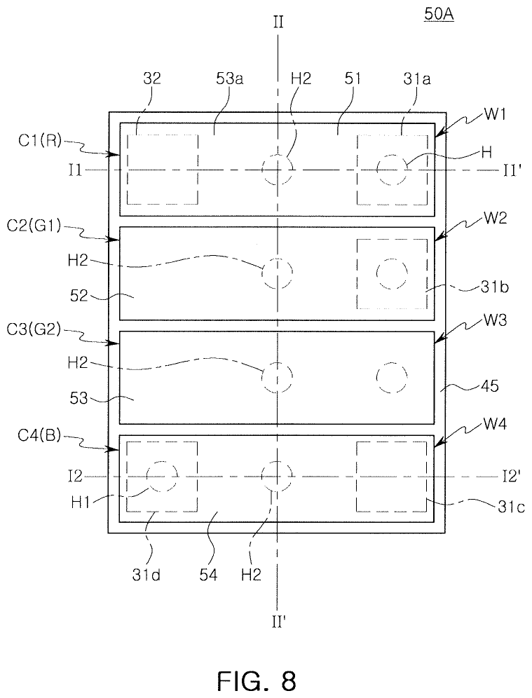

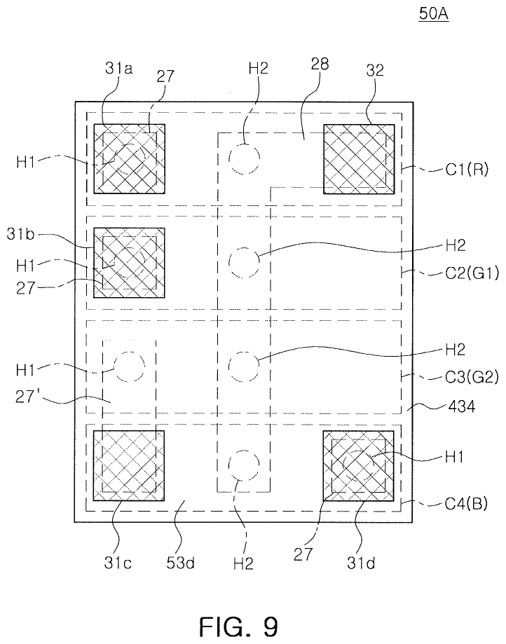

The first and second through-holes H1 and H2 may expose portions of the first and second contact electrodes 23 and 24 to connect them to the first and second connection electrodes 27 and 28. The first connection electrodes 27 may respectively be in the four first through-holes H1 and isolated from one another by the insulating layer 21. The second connection electrode 28 may have portions of the electrodes formed in the four second through-holes H2 connected to one another. The electrode portion may vary depending on arrangement of the cells and the electrode pads. The configuration above will be described in greater detail later (see FIGS. 8 and 9).

The light emitting diode module 50 may further include an encapsulation layer 34 encapsulating the cell array CA and exposing the first electrode pads 31a, 31b, 31c, and 31d, and the second electrode pad 32. The encapsulation layer 34 may extending along outer sidewalls of the light emitting diode module 50. The encapsulation layer 34 may have a relatively high Young's modulus to firmly support the light emitting diode module 50. The encapsulation layer 34 may also include a material having high thermal conductivity to emit heat effectively from the first to fourth light emitting diode cells C1, C2, C3, and C4. For example, the encapsulation layer 34 may be an epoxy resin or a silicone resin. The encapsulation layer 34 may further include light-reflecting particles for reflecting light, e.g., titanium dioxide (TiO₂), an aluminum oxide (Al₂O₃), and the like.

The light blocking walls 45 may have first to fourth windows W1, W2, W3, and W4 in portions corresponding to the first to fourth light emitting diode cells C1, C2, C3, and C4. The first to fourth windows W1, W2, W3, and W4 provide as spaces for the first to fourth light adjusting portions 51, 52, 53, and 54. The light blocking walls 45 may include a material for blocking light to prevent interference between beams of light transmitting the first to fourth light adjusting portions 51, 52, 53, and 54. For example, the light blocking walls 45 may include a reflective material including a black matrix resin or light-scattering particles.

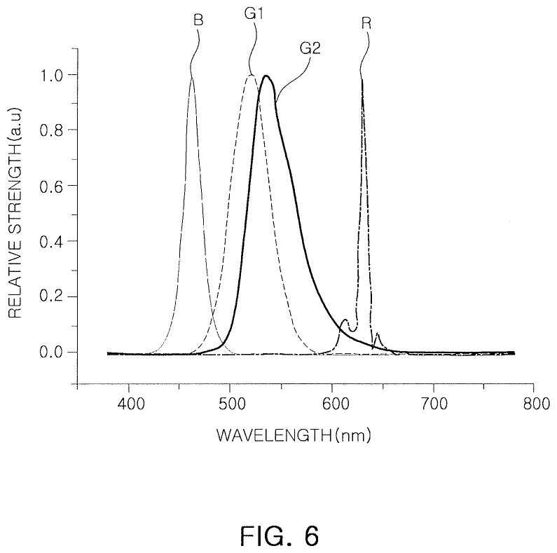

FIG. 6 is light emitting spectrums of an LED module according to an example embodiment. FIG. 6 illustrates light emitting spectrums obtained from a light emitting diode module (embodiment) according to an example embodiment. Red light, first green light, second green light, and blue light may be provided by the first to fourth light adjusting portions described above. Respective spectrums of red light, first green light, second green light, and blue light are indicated as “R,” “G1,” “G2,” and “B,” respectively.

The colors of the light emitting spectrums illustrated in FIG. 6 may respectively have peak wavelengths and full widths at half maximum as indicated in Table 1 below.

TABLE 1

| | B | G1 | G2 | R |
|---|---|---|---|---|
| Peak Wavelength | 463 | 520 | 535 | 630 |
| (nm) | | | | |
| Full Width at Half | 20 | 43.6 | 50 | 12 |
| Maximum (nm) | | | | |

In contrast, a general light emitting diode module (comparative example) may include three cells for red light, single green light, and blue light, and the colors or light may have peak wavelengths and full widths at half maximum as indicated in Table 2 below such that the colors of light may secure a relatively high level of covering rate (e.g., 97%) with reference to DCI.

TABLE 2

| | B | G | R |
|---|---|---|---|
| Peak Wavelength | 455 | 525 | 650 |
| (nm) | | | |
| Full Width at Half | 16 | 62 | 75 |
| Maximum (nm) | | | |

Color gamuts of the light emitting diode modules (embodiment and comparative example) under the conditions in Tables 1 and 2 may be represented in the CIE 1931 coordinate system illustrated in FIG. 7. Respective coordinates of the color gamuts in the embodiment and in the comparative example are indicated in Tables 3 and 4 below.

TABLE 3

| | B | G1 | G2 | R |
|---|---|---|---|---|
| X | 0.1371 | 0.1510 | 0.3177 | 0.6899 |
| Y | 0.0517 | 0.7043 | 0.6523 | 0.3020 |

TABLE 4

| | B | G | R |
|---|---|---|---|
| X | 0.1530 | 0.2465 | 0.6744 |
| Y | 0.0657 | 0.6933 | 0.3217 |

As indicated in Table 5 and FIG. 7, the light emitting diode module in the embodiment may have higher color reproducibility than color reproducibility of the light emitting diode module in the comparative example, and the color gamut of the light emitting diode module in the embodiment may cover 90% or higher of a BT.2020 region in the CIE 1931 coordinate system.

TABLE 5

| Examination of Color | | |
|---|---|---|
| Gamut | Embodiment | Comparative Example |
| s-RGB | 99.9% | 99.9% |
| DCI | 98.9% | 97.4% |
| BT.2020 | 92.4% | 72.2% |

Thus, by configuring the light emitting diode module such that the green light is provided as the first green light and the second green light, and the blue light has a higher peak wavelength that a peak wavelength of blue light in a general light emitting diode module, a relatively high color reproducibility may be secured.

With regard to wavelength conditions of each color in the example embodiment, the blue light B may have a peak wavelength of 460 nm to 470 nm. The first green light may have a peak wavelength of 510 nm to 525 nm and a full width at half maximum of 50 nm or less, and the second green light may have a peak wavelength of 530 nm to 540 nm and a full width at half maximum of 55 nm or less. The red light may have a peak wavelength of 620 nm to 640 nm and a full width at half maximum of 30 nm or less.

At least one of the first to third wavelength converting portions may include a quantum dot converting the blue light. For example, the quantum dot may include at least one of CdSe/CdS, CdSeZnS, CdSe/ZnS, PbS/ZnS, InP/GaP/ZnS, and the like. The quantum dot may have a relatively narrow full width at half maximum of 10 nm or less.

In the example embodiments, the first wavelength converting portion may include a fluoride particle represented by a compositional formula AxMFy:Mn4+, where A is one material selected from Li, Na, K, Rb and Cs, M is one material selected from Si, Ti, Zr, Hf, Ge, and Sn, and the compositional formula may satisfy 2≤x≤3 and 4≤y≤7. For example, a red phosphor may include a fluoride phosphor represented as K2SiF6:Mn4+.

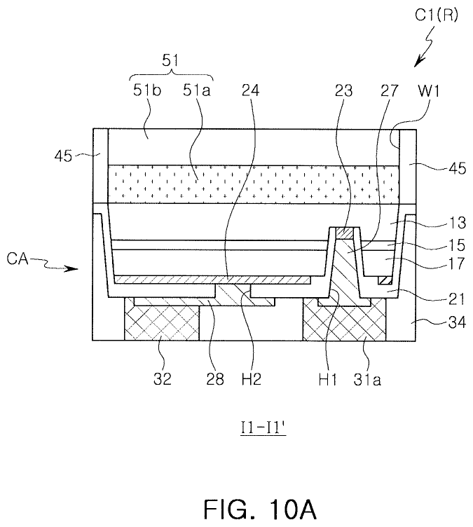

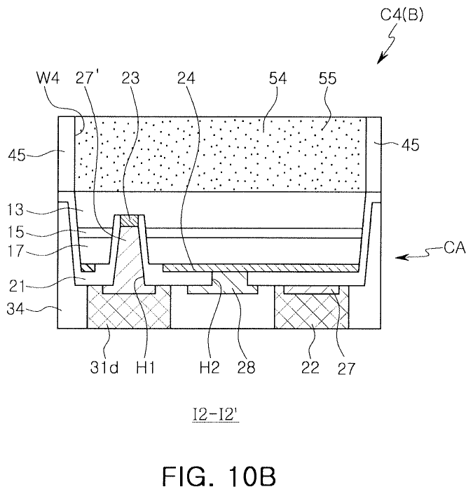

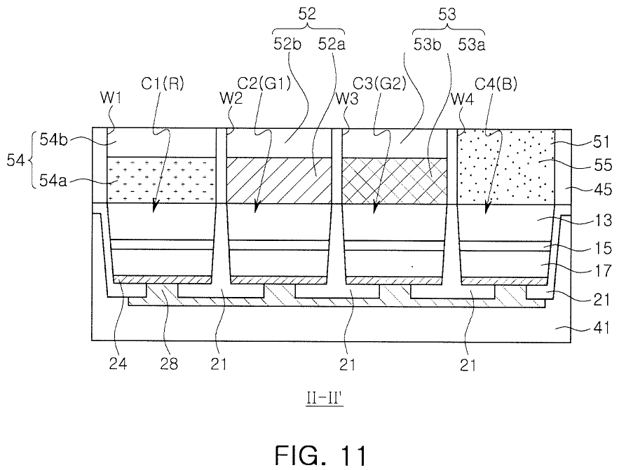

The light emitting diode module in the example embodiment may have a variety of layouts. The various layout structures are illustrated in FIGS. 8 through 11. FIGS. 8 and 9 are a top diagram and a bottom diagram, respectively, illustrating an LED module according to example embodiments. FIGS. 10A and 10B are side cross-sectional diagrams respectively taken along lines I1-I1′ and I2-I2′ of an LED module of FIGS. 8 and 9. FIG. 11 is a side cross-sectional diagram taken along a line II-II′ of an LED module of FIGS. 8 and 9.

Referring to FIGS. 8 to 11, a light emitting diode module 50A may have a structure similar to that of the light emitting diode module 50 illustrated in FIGS. 1 to 4 apart from the different arrangements of the first to fourth light emitting diode cells C1, C2, C3, and C4, and the electrode pads. The descriptions of the other elements in the example embodiment may be the same as the descriptions of the same or similar elements of the light emitting diode module 50 illustrated in FIGS. 1 to 4 unless otherwise indicated.

As illustrated in FIGS. 8 and 9, the light emitting diode module 50A may include first to fourth light emitting diode cells C1, C2, C3, and C4 arranged in parallel in a horizontal direction, e.g., extend along a row direction and spaced apart along a column direction. The light emitting diode module 50A may further include four first electrode pads 31a, 31b, 31c, and 31d respectively connected to the four light emitting diode cells C1, C2, C3, and C4, and a second electrode pad 32 commonly connected to the four light emitting diode cells C1, C2, C3, and C4, similarly to the aforementioned exemplary embodiment.

Referring to FIGS. 10A and 11, the four light emitting diode cells C1, C2, C3, and C4 may be independently connected to first conductive semiconductor layers 13 of the first to fourth light emitting diode cells C1, C2, C3, and C4 by four first connection electrodes 27, respectively. The second electrode pad 32 may be commonly connected to second conductive semiconductor layers 17 of the first to fourth light emitting diode cells C1, C2, C3, and C4 by a single second connection electrode 28. The first and second connection electrodes 27 and 28 may respectively be connected to the first and second conductive semiconductor layers 13 and 17 through first and second through-holes H1 and H2 formed on insulating portions 21. Depending on an arrangement of the light emitting diode cell, a position of the electrode pad may be altered such that, rather than overlapping the related light emitting diode cell, the electrode pad may overlap other light emitting diode cells. For example, as illustrated in FIGS. 9 and 10B, a first connection electrode 27′ of the third light emitting diode cell C3 may extend to a region of the insulating portion 21 positioned on the fourth light emitting diode cell C4, and the first electrode pad 31c may be formed on the extended region of the first connection electrode 27′.

The first to fourth light adjusting portions 51, 52, 53, and 54 in the example embodiment may be configured to provide red light R, first green light G1, second green light G2, and blue light B, similarly to the aforementioned example embodiment. Differently from the aforementioned example embodiment, the fourth light adjusting portion 54 may include a transparent resin layer containing a light absorbing material 55 to reduce an optical output. As the first to third light adjusting portions 51, 52, and 53 include a wavelength converting material, the first to third light adjusting portions 51, 52, and 53 may have a reduced efficiency. Accordingly, light emitted from the first to third light adjusting portions 51, 52, and 53 may have a lower output than an output of light emitted from the fourth light adjusting portion 54. Thus, to alleviate differences in output of the four cells included in each sub-pixel, the fourth light adjusting portion 54 may further include the light absorbing material 55 partially absorbing the blue light. The light absorbing material 55 may include a pigment or a dye for absorbing light. As the first to third wavelength converting portions 51a, 52a, and 53a include different wavelength converting materials, the first to third wavelength converting portions 51a, 52a, and 53a may include different levels of optical outputs in accordance with efficiencies of the wavelength converting materials. To reduce the differences in optical output, at least one of the first to third light adjusting portions 51, 52, and 53 may further include the light absorbing material.

As a material for converting a wavelength of light emitted from the light emitting diode cells in the example embodiment, various materials such as a phosphor and/or a quantum dot may be used. The phosphor may have compositional formulas and colors as below.

Oxide: green Y₃Al₅O₁₂:Ce, Tb₃Al₅O₁₂:Ce, and Lu₃Al₅O₁₂:Ce

Silicate: green (Ba,Sr)₂SiO₄:Eu, and yellow and orange (Ba,Sr)₃SiO₅:Ce

Nitride: green β-SiAlON:Eu, yellow La₃Si₆N₁₁i:Ce, orange α-SiAlON:Eu, and red CaAlSiN₃:Eu, Sr₂Si₅N₈:Eu, SrSiAl₄N₇:Eu, SrLiAl₃N₄:Eu, and Ln₄₋ₓ(Eu_{z}M_{1-z})ₓSi_{12-y}Al_{y}O_{3+x+y}N_{18-x-y} (0.5≤x≤3, 0≤z<0.3, 0<y≤4, and where Ln may be at least one element selected from group III elements and rare earth elements, and M may be at least one of Ca, Ba, Sr, and Mg)

Fluoride: KSF-type red K₂SiF₆:Mn⁴⁺, K₂TiF₆:Mn⁴⁺, NaYF₄:Mn⁴⁺, NaGdF₄:Mn⁴⁺, K₃SiF₇:Mn⁴⁺

A composition of a phosphor may need to be conformed to stoichiometry, and different elements of groups in the periodic table may be substituted for the elements. For example. Ba, Ca, Mg, or the like, of an alkanine earth element (II) group may be substituted for Sr, and Tb, Lu, Sc, Gd, or the like, of lanthanide series may be substituted for Y. Also, Ce, Tb, Pr, Er, and Yb may be substituted for Eu, an actant, or the like, in accordance with a desired energy level, and an actant alone, a co-actant, or the like, may be applied to alter properties.

A fluoride red phosphor may be coated with a fluoride which does not include Mn or may further include an organic material coated on a surface of a phosphor or on a surface of a fluoride-coating, which does not include Mn, to improve reliability in high temperature/high humidity. With regard to the fluoride red phosphor described above, the fluoride red phosphor may implement a narrow full width at half maximum (narrow FWHM) differently from other phosphors. Thus, the fluoride red phosphor may be used in a high resolution TV, e.g., a UHD TV.

Also, as a material of the wavelength converting portion, the aforementioned wavelength converting materials such as a quantum dot (QD) may be used, which may replace a phosphor or may be mixed with a phosphor.

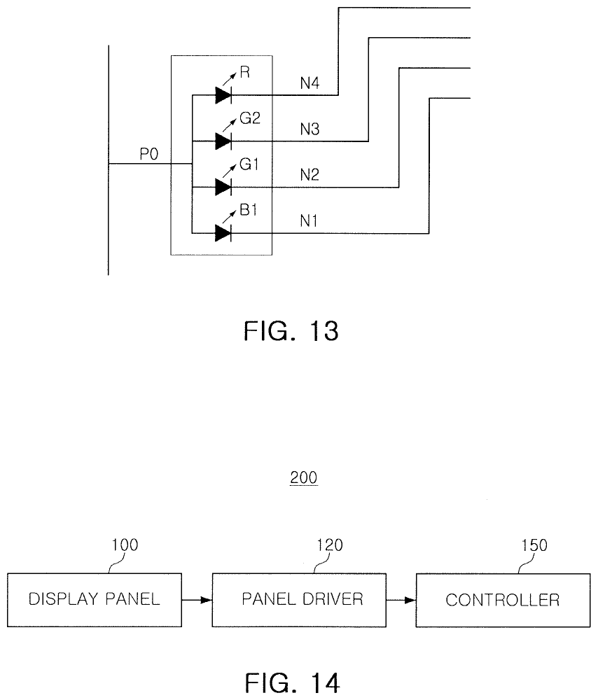

FIG. 12 is a perspective diagram illustrating a display panel in which an LED module illustrated in FIG. 1 is employed. FIG. 13 is a diagram illustrating an example of a circuit of a pixel region of a display panel illustrated in FIG. 12.

Referring to FIG. 12, a display panel 100 may include a circuit substrate 201 and a plurality of light emitting diode modules 50 arranged on the circuit substrate 201. The display panel 100 may further include a black matrix 210 on the circuit substrate 201. The black matrix 210 may serve as guide line defining mounting regions of the plurality of light emitting diode modules 50.

A color of the black matrix 210 may not be limited to black. A white matrix may be used, or green, or the like, may also be used depending on usage of a product or an entity using a product. A transparent matrix may also be used if desired. The white matrix may further include a reflective material or a scattering material. The black matrix 210 may include at least one material among a polymer including a resin, a ceramic, a semiconductor, or a metal.

The plurality of light emitting diode modules 50 may include four sub-pixels respectively providing red light R, first green light G1, second green light G2, and blue light B. The pixels PA may be consecutively arranged. The sub-pixels may include LED cells and light adjusting portions as illustrated in FIGS. 1 to 4. Other arrangements may be implemented. For example, as in the light emitting diode module 50A illustrated in FIGS. 8 to 11, a single pixel PA may include sub-pixels R, G1, G2, and B arranged in the same direction.

In accordance with the arrangement, an electrode arrangement for independently driving the light emitting diode cells of each of the light emitting diode modules 50 and 50A may be implemented as illustrated in FIGS. 2 and 9, and each electrode arrangement may be connected to a circuit of the circuit substrate 201, and the circuit may independently drive the sub-pixels R, G1, G2, and B of each pixel PA. For example, the circuit substrate 201 may be a TFT substrate having a thin film transistor (TFT) circuit.

FIG. 13 illustrates an example configuration of a circuit of a single pixel of the display panel 100 illustrated in FIG. 12. In the diagram, “R,” “G1,” “G2,” and “B” may refer to respective light emitting diode cells included in a sub-pixel in the light emitting diode module 50 in FIG. 12.

The light emitting diode cells R, G1, G2, and B included in the sub-pixel may have various configurations of circuit connection to be independently driven. For example, anodes of the first to fourth light emitting diode cells R, G1, G2, and B may be connected to a drain of a P-MOSFET along with anodes of the first to fourth light emitting diode cells R, G1, G2, and B in the same rows, and cathodes N1, N2, N3, and N4 of the first to fourth light emitting diode cells R, G1, G2, and B may be connected to a constant current input terminal of a light emitting diode driving circuit in each sub-pixel in the same columns. A source of the P-MOSFET may be connected to a power supplying terminal and a gate may be connected to a control port for supplying power to rows. A drain of a single P-MOSFET may be turned on through a controller, power may be supplied to anodes of the light emitting diode in the respective row, and simultaneously, an output port for outputting a constant current control signal may control the light emitting diode driving circuit, thereby lighting the light emitting diodes to which power is supplied. In the example embodiments, the light emitting diode circuits may be configured such that the second and third light emitting diode cells C2 and C3 may be driven to operate as a single green sub-pixel. For example, by adjusting a ratio between strengths of the first and second green lights G1 and G2 emitted from the second and third light emitting diode cells C2 and C3, green light having desired chromaticity may be provided while maintaining a certain level of strength of green light.

FIG. 14 is a block diagram illustrating a display device according to example embodiments.

Referring to FIG. 14, a display panel 100 illustrated in FIG. 13 may be provided in a display device 200 along with a panel driver 120 and a controller 250. The display device may be implemented as a variety of electronic devices such as a TV, an electronic blackboard, an electronic table, a large format display (LFD), a smartphone, a tablet, a desktop PC, a laptop, and the like.

The panel driver 120 may drive the display panel 100 and the controller 150 may control the panel driver 120. The panel driver 120 controlled by the controller 150 may be configured such that a plurality of sub-pixels including R, G1, G2, and B may be turned on and off independently of one another.

For example, the panel driver 120 may transmit a clock signal having a certain driving frequency to each of the plurality of sub-pixels and may turn on or turn off the plurality of sub-pixels. The controller 150 may control the panel driver 120 such that the plurality of sub-pixels may be turned on in predetermined group unit in response to an input image signal, thereby displaying a desired image on the display panel 100.

According to the aforementioned example embodiments, by configuring the light emitting diode module to include the four sub-pixels respectively emitting red light, blue light, and first green light and second green light, which are different from each other, improved color reproducibility may be implemented. The color gamut of the light emitting diode module may cover 90% or higher (desirably, 95% or higher) of a BT.2020 region in the CIE 1931 coordinate system.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A light emitting diode module, comprising:
a cell array including first to fourth light emitting diode cells, each cell having a first conductive semiconductor layer, an active layer, and a second conductive semiconductor layer, the cell array having a first surface and a second surface opposite to the first surface;
first to fourth light adjusting portions on the second surface of the cell array to respectively correspond to the first to fourth light emitting diode cells, to provide red light, first green light, second green light, and blue light, respectively;
light blocking walls between the first to fourth light adjusting portions to isolate the first to fourth light adjusting portions from one another; and
an electrode portion on the first surface of the cell array, and electrically connected to the first to fourth light emitting diode cells to selectively drive the first to fourth light emitting diode cells.

2. The light emitting diode module as claimed in claim 1, wherein:
the first to fourth light emitting diode cells emit blue light, and
the first light adjusting portion includes a first wavelength converting portion converting the blue light into red light, the second light adjusting portion includes a second wavelength converting portion converting the blue light into first green light, and the third light adjusting portion includes a third wavelength converting portion converting the blue light into second green light.

3. The light emitting diode module as claimed in claim 2, wherein the first green light has a peak wavelength of 510 nm to 525 nm, and the second green light has a peak wavelength of 530 nm to 540 nm.

4. The light emitting diode module as claimed in claim 3, wherein the first green light and the second green light each have a full width at half maximum of 55 nm or less.

5. The light emitting diode module as claimed in claim 3, wherein the blue light has a peak wavelength of 460 nm to 470 nm, and the red light has a peak wavelength of 620 nm to 640 nm.

6. The light emitting diode module as claimed in claim 5, wherein the red light and the blue light each have a full width at half maximum of 30 nm or less.

7. The light emitting diode module as claimed in claim 2, wherein the first to third light adjusting portions are respectively on the first to third wavelength converting portions, and further include filters blocking the blue light.

8. The light emitting diode module as claimed in claim 1, wherein the light emitting diode module has a color gamut covering 90% or higher of a BT.2020 region in the CIE 1931 coordinate system.

9. The light emitting diode module as claimed in claim 1, wherein the fourth light adjusting portion includes a transparent resin layer containing a light absorbing material for reducing an optical output.

10. The light emitting diode module as claimed in claim 1, wherein:
the first to fourth light emitting diode cells emit ultraviolet light, and
the first to fourth light adjusting portions respectively include first to fourth wavelength converting portions respectively converting the ultraviolet light into the red light, the first green light, the second green light, and the blue light.

11. The light emitting diode module as claimed in claim 1, wherein the cell array further includes reflective insulating portions respectively surrounding the first to fourth light emitting diode cells to isolate the first to fourth light emitting diode cells from one another, and the light blocking walls are connected to the reflective insulating portions.

12. The light emitting diode module as claimed in claim 11, wherein the reflective insulating portion includes a distributed Bragg reflector structure in which a plurality of insulating films having different refractive indices are alternately stacked.

13. The light emitting diode module as claimed in claim 11, wherein the reflective insulating portions each further include insulating layers respectively surrounding the first to fourth light emitting diode cells, and metal reflective layers on the insulating layers.

14. The light emitting diode module as claimed in claim 1, wherein the electrode portion includes a first common electrode commonly connected to the first conductive semiconductor layers of the first to fourth light emitting diode cells, and first to fourth individual electrodes respectively connected to the second conductive semiconductor layers of the first to fourth light emitting diode cells.

15. A light emitting diode module, comprising:
a cell array including first to fourth light emitting diode cells, each cell having first and second conductive semiconductor layers, and an active layer between the first and second conductive semiconductor layers, and emitting blue light having a peak wavelength of 460 nm to 470 nm, the cell array having a first surface and a second surface opposite to the first surface;
reflective insulating portions respectively surrounding the first to fourth light emitting diode cells to isolate the first to fourth light emitting diode cells from one another;
light blocking walls in regions corresponding to the reflective insulating portions, and providing first to fourth windows respectively for the first to fourth light emitting diode cells;
first to third light adjusting portions respectively on the first to third windows, and converting the blue light into red light, first green light, and second green light; and
an electrode portion on the first surface of the cell array, and electrically connected to the first to fourth light emitting diode cells to selectively drive the first to fourth light emitting diode cells,
wherein the first green light has a peak wavelength of 510 nm to 525 nm and a full width at half maximum of 50 nm or less, the second green light has a peak wavelength of 530 nm to 540 nm and a full width at half maximum of 55 nm or less, and the red light has a peak wavelength of 620 nm to 640 nm and a full width at half maximum of 30 nm or less.

16. (canceled)

17. The light emitting diode module as claimed in claim 15, wherein the first light adjusting portion includes a first wavelength converting portion converting the blue light into red light, the second light adjusting portion includes a second wavelength converting portion converting the blue light into first green light, and the third light adjusting portion includes a third wavelength converting portion converting the blue light into second green light.

18. The light emitting diode module as claimed in claim 17, wherein at least one of the first to third wavelength converting portions includes a quantum dot converting the blue light.

19. (canceled)

20. The light emitting diode module as claimed in claim 17, wherein the first to third light adjusting portions include a filter blocking the blue light.

21. The light emitting diode module as claimed in claim 15, further comprising a transparent resin on the fourth window.

22. A display device, comprising:
a display panel;
a panel driver for driving the display panel; and
a controller for controlling the panel driver,
wherein the display panel includes a plurality of light emitting diode modules provided as a plurality of pixels,
wherein the plurality of light emitting diode modules each include:
a cell array including first to fourth light emitting diode cells, each cell having a first conductive semiconductor layer, an active layer, and a second conductive semiconductor layer, the cell array having a first surface and a second surface opposite to the first surface,
first to fourth light adjusting portions on the second surface of the cell array to respectively correspond to the first to fourth light emitting diode cells to provide red light, first green light, second green light, and blue light, respectively,
light blocking walls between the first to fourth light adjusting portions to isolate the first to fourth light adjusting portions from one another; and
an electrode portion on the first surface of the cell array, and electrically connected to the first to fourth light emitting diode cells to selectively drive the first to fourth light emitting diode cells.
